(19) United States
(12) Patent Application Publication
(10) Pub. No.: US 2025/0240922 A1
(43) Pub. Date: Jul. 24, 2025

(54) BOILING ENHANCEMENT COMPONENT AND IMMERSION COOLING SYSTEM HAVING THE SAME

(71) Applicant: Wiwynn Corporation, New Taipei City (TW)

(72) Inventors: Chih-Cheng CHIEN, New Taipei City (TW); Yi CHENG, New Taipei City (TW); Zi-Ping WU, New Taipei City (TW); Tsung-Han LI, New Taipei City (TW)

(21) Appl. No.: 19/014,812

(22) Filed: Jan. 9, 2025

Related U.S. Application Data
(60) Provisional application No. 63/622,164, filed on Jan. 18, 2024.

(30) Foreign Application Priority Data
Jan. 2, 2025 (TW) 114100185

(51) Int. Cl. H05K 7/20

(52) U.S. Cl. CPC H05K 7/20327; H05K 7/203

(57) ABSTRACT

A boiling enhancement component and an immersion cooling system having the same are provided. The boiling enhancement component includes a heat conductive portion and a boiling formation portion. The heat conductive portion has a first surface contacting a heat source and a second surface; the boiling formation portion is located on the second surface and includes a plurality of bubble disturbance regions. When a fluid medium boils on the boiling formation portion to generate bubbles, the bubble disturbance regions redirect the rising paths of at least some of the bubbles, thereby promoting bubble aggregation and accelerating the detachment of bubbles from the boiling enhancement component. Another embodiment provides an immersion cooling system, which includes a tank and the boiling enhancement component, the tank having a containing space to contain the fluid medium, and the boiling enhancement component being disposed in the containing space and immersed in the fluid medium.

### CROSS-REFERENCE TO RELATED APPLICATION

This non-provisional application claims the benefit of U.S. provisional application Ser. No. 63/622,164, filed on Jan. 18, 2024 and claims the priority of Patent Application No. 114100185, filed in Taiwan, R.O.C. on Jan. 2, 2025. The entire of the above-mentioned patent applications is hereby incorporated by references herein and made a part of the specification.

### BACKGROUND

### Technical Field

The present disclosure provides a boiling enhancement component and an immersion cooling system having the same, and particularly relates to an immersion cooling system applicable to cooling an electronic device.

### Related Art

Immersion cooling systems are highly efficient heat dissipation methods widely used in high-power electronic devices. Among them, the boiler is a critical heat exchange component. Conventional boilers are made of metal materials with excellent thermal conductivity, and their surfaces perform heat exchange over an entire flat plane, transferring the heat generated by electronic components to the cooling liquid. During system operation, the boiler surface facilitates the boiling and evaporation of the cooling liquid due to heat transfer, generating a large number of bubbles that carry heat away from the electronic components.

However, small bubbles initially formed lack sufficient buoyancy to detach immediately from the boiler surface. These bubbles must grow larger or coalesce with other bubbles to gain the buoyancy needed to rise and remove heat. During this period, when the bubbles adhere to the boiler surface, they form a bubble film that obstructs direct contact between the liquid and the heat dissipation surface. This phenomenon, known as the bubble film effect, creates a significant thermal resistance that impairs the heat exchange efficiency of the boiler, thereby reducing the overall cooling performance of the system. This issue has become a major bottleneck in enhancing the efficiency of immersion cooling systems.

### SUMMARY

An embodiment of the present disclosure provides a boiling enhancement component, which includes a heat conductive portion and a boiling formation portion; the heat conductive portion has a first surface configured to contact a heat source, and a second surface; the boiling formation portion is located on the second surface of the heat conductive portion and includes a plurality of bubble disturbance regions. In response to that a fluid medium boils on the boiling formation portion to generate a plurality of bubbles, the bubble disturbance regions are configured to redirect a rising path of at least some of the bubbles.

An embodiment of the present disclosure provides a boiling enhancement component, which includes a heat conductive portion and a plurality of protrusions; the heat conductive portion includes a first surface configured to contact a heat source, and a second surface; the plurality of protrusions are located on the second surface of the heat conductive portion, arranged along the gravity direction, and extend longitudinally; and a plurality of bubble guide channels are formed among the protrusions. The surfaces of the protrusions forming the bubble guide channels include at least one among a plurality of recessed portions and a plurality of raised portions to redirect a rising path of a plurality of bubbles.

An embodiment of the present disclosure provides an immersion cooling system, which includes a tank and a boiling enhancement component; the tank has a containing space configured to accommodate a fluid medium; and the boiling enhancement component is disposed in the containing space of the tank and immersed in a fluid medium. The boiling enhancement component includes a heat conductive portion and a boiling formation portion; the heat conductive portion has a first surface configured to contact a heat source, and a second surface; and the boiling formation portion is located on the second surface of the heat conductive portion and the boiling formation portion includes a plurality of bubble disturbance regions. In response to that a fluid medium boils on the boiling formation portion to generate a plurality of bubbles, the bubble disturbance regions are configured to redirect a rising path of at least some of the bubbles.

The summary presented above does not include an exhaustive list of all aspects of the instant disclosure. It is provided merely to introduce certain concepts and not to identify any key or essential features of the claimed subject matters.

### BRIEF DESCRIPTION OF THE DRAWINGS

FIG. 1A is a front view of an embodiment of a boiling enhancement component according to the present disclosure.

FIG. 1B is a perspective view of an embodiment of a boiling enhancement component according to the present disclosure.

FIG. 2A to FIG. 2D and FIG. 3A to FIG. 3D are front views of an embodiment of a boiling enhancement component according to the present disclosure.

FIG. 4A is a bottom view of an embodiment of a boiling enhancement component disposed in a circuit board according to the present disclosure.

FIG. 4B is a front view of an embodiment of a boiling enhancement component according to the present disclosure.

FIG. 5 is a diagram showing the relationship between temperature and power after the actual operation of an embodiment of the boiling enhancement component according to the present disclosure.

FIG. 6A is a front view of an embodiment of a boiling enhancement component according to the present disclosure.

FIG. 6B is a perspective view of an embodiment of a boiling enhancement component according to the present disclosure.

FIG. 7 is a schematic diagram of an embodiment of an immersion cooling system according to the present disclosure.

### DETAILED DESCRIPTION

Various embodiments are presented below for detailed description, and the embodiments are only used as examples and do not limit the scope of the present disclosure. In addition, some elements are omitted in the drawings in the embodiments to clearly show the technical features of the present disclosure. Furthermore, the same reference numerals will be used for representing the same or similar elements in all drawings, and the drawings of the present disclosure are only for schematic illustration, which may not be drawn to scale, and all details may not be fully presented in the drawings.

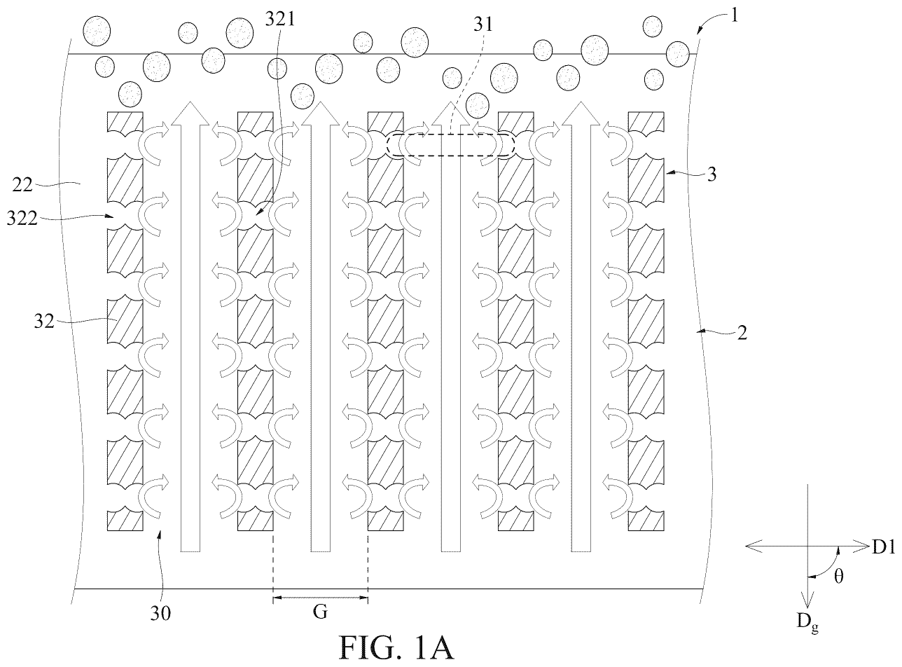

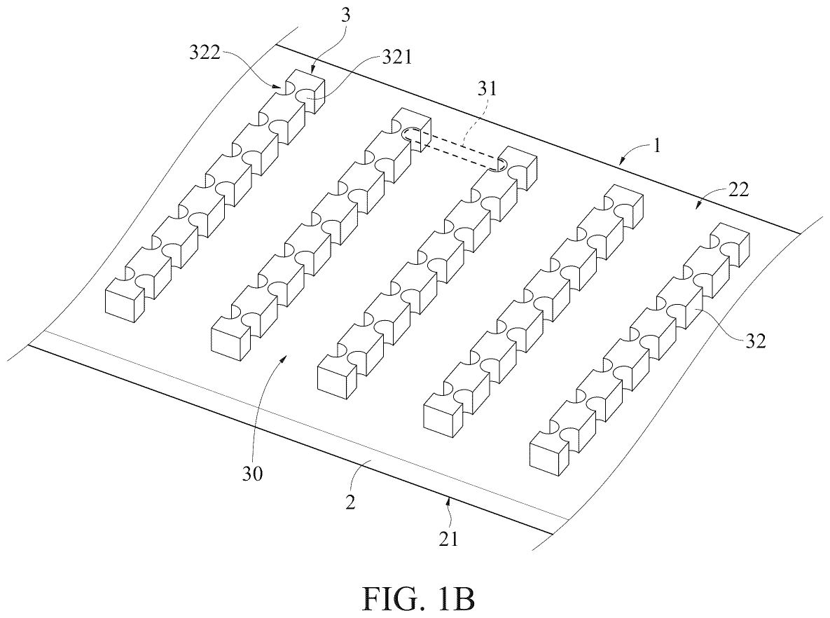

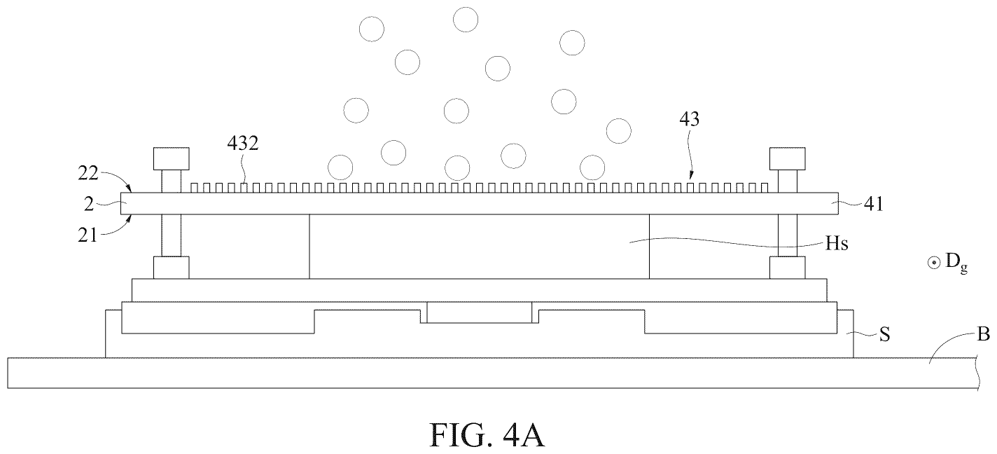

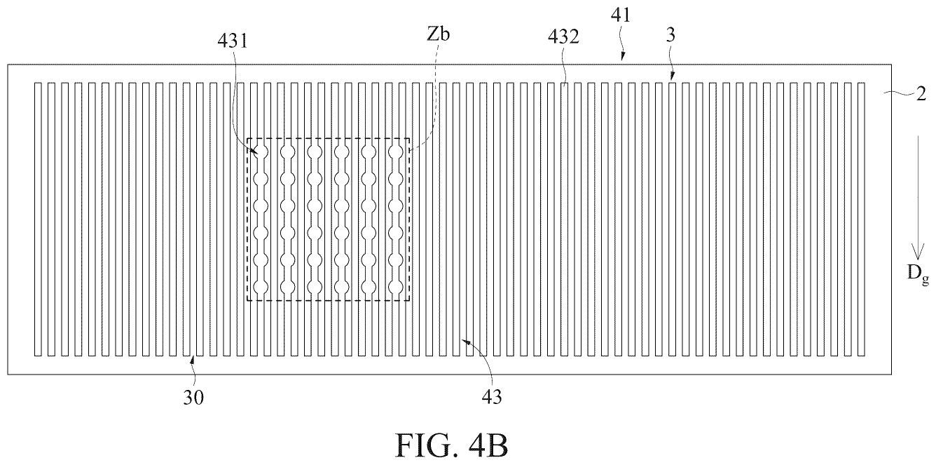

With reference to FIG. 1A and FIG. 1B, FIG. 1A is a front view of an embodiment of a boiling enhancement component according to the present disclosure, and FIG. 1B is a perspective view of an embodiment of a boiling enhancement component 1 according to the present disclosure. As shown in the figures, the boiling enhancement component 1 includes a heat conductive portion 2 and a boiling formation portion 3. The heat conductive portion 2 has a first surface 21 and a second surface 22. The first surface 21 is configured to contact a heat source Hs (see FIG. 4A). The boiling formation portion 3 is located on the second surface 22 of the heat conductive portion 2 and includes a plurality of bubble disturbance regions 31. When a fluid medium undergoes boiling in the boiling formation portion 3 and generate bubbles, the bubble disturbance regions 31 can redirect the rising paths of at least some of the bubbles to facilitate bubble aggregation.

In some embodiments, the first surface 21 and the second surface 22 are two corresponding surfaces, such as an upper surface and a lower surface. In other embodiments, the first surface 21 and the second surface 22 may also be adjacent surfaces, such as two surfaces perpendicular to each other. Additionally, the heat source Hs (see FIG. 4A) is typically a chip or other high-power electronic device, such as a CPU, GPU, TPU, FPGA, ASIC, XPU, NPU, DPU, or other semiconductor integrated circuits with high thermal design power (TDP).

In some embodiments, the boiling formation portion 3 includes a plurality of protrusions 32. The protrusions 32 are elongated and arranged parallel to each other, extending along the gravity direction Dg. A specific spacing G is reserved between adjacent protrusions 32 to form a bubble guide channel 30. The bubble guide channels 30 are substantially parallel to the gravity direction Dg. In addition, each protrusion 32 has a plurality of recessed portions 321, each recessed portion 321 is provided with an opening 322. The opening 322 faces the bubble guide channel 30. In other words, each recessed portion 321 is in communication with its adjacent bubble guide channel 30.

The bubble guide channels 30 and the recessed portions 321 together form the bubble disturbance regions 31. The bubble disturbance regions 31 are located in the bubble guide channels 30 and is configured to direct at least some of the bubbles along in a specific direction D1, so as to redirect the rising path of the bubbles, increase the disturbance of the bubbles and the fluid medium, and promote the aggregation of the bubbles. The specific direction D1 forms an angle θ with respect to the gravity direction Dg, where the angle θ ranges between 90 degrees and 180 degrees.

In the embodiments shown in FIGS. 1A and 1B, the openings 322 of the recessed portions 321 are substantially perpendicular to the bubble guiding channel 30. Therefore, the angle θ between the specific direction D1 and the gravity direction Dg is 90 degrees. Additionally, the recessed portions 321 are respectively disposed on the two opposite sides of the protrusions 32 and are interconnected. The recessed portions 321 are semicircular grooves extending along the thickness direction of the protrusions 32. In other embodiments, the recessed portions 321 may also be elliptical grooves, rounded rectangular grooves, stadium-shaped grooves, or other geometrically polygonal grooves.

During system operation, the fluid medium is heated and boiled at the boiling formation part 3, generating the plurality of bubbles. Since bubbles primarily form on the surface of the boiling formation part 3, particularly near the sidewalls of the protrusions 32, a large number of bubbles are generated at these locations. These bubbles rise along the bubble guiding channel 30. However, the rising process of the bubbles is influenced by various factors, resulting in irregular bubble trajectories. For example, bubble motion may be affected by interactions between bubbles, disturbances from hydrodynamic effects, local movements of the fluid medium, and minor perturbations. Additionally, variations in the density and viscosity of the fluid medium can also collectively influence bubble motion.

Furthermore, during the irregular rising process of the bubbles, the presence of the bubble disturbance zone 31 further enhances the mutual disturbances between the fluid medium and the bubbles. This disturbance not only facilitates the detachment of bubbles from the boiling formation portion 3 but also increases the likelihood of bubble collisions and aggregation. When bubbles aggregate, larger bubbles are formed, altering their dynamic characteristics and further improving boiling efficiency.

When collisions occur between bubbles, their surface tension causes bubble films to deform, eventually leading to the rupture of the bubble membranes and the merging of two bubbles into a larger one. This coalescence process is driven by surface tension, as surface tension strives to minimize the total surface area of the bubbles. Therefore, when two bubbles come close to each other, surface tension facilitates their fusion into a single entity.

After small bubbles aggregate into larger bubbles, the rising speed of the larger bubbles increases significantly. This is because the buoyant force of a bubble is proportional to its volume. Larger bubbles have greater volume and surface area, enabling them to displace more liquid and reduce resistance during the rising process. At the same time, the buoyant force increases substantially, allowing larger bubbles to rise at a higher speed.

Additionally, in certain embodiments, by configuring the boiling formation portion 3 with bubble guide channels 30 and recessed portions 321, the heat exchange surface area between the boiling formation portion 3 and the fluid medium can be significantly increased. Due to the enlarged heat exchange surface area, the boiling effect of the fluid medium is enhanced, resulting in the generation of more bubbles. This not only significantly improves overall heat dissipation efficiency but also increases the likelihood of bubble collisions and aggregation, thereby further enhancing heat dissipation performance.

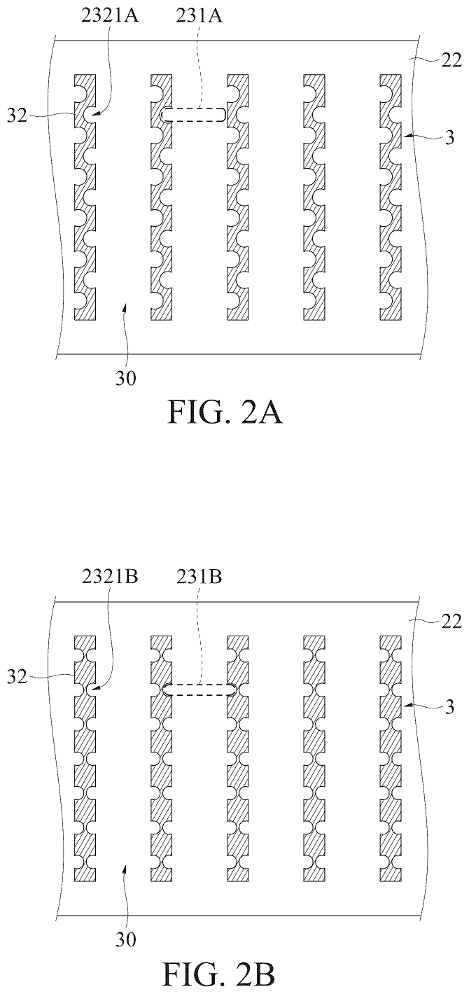

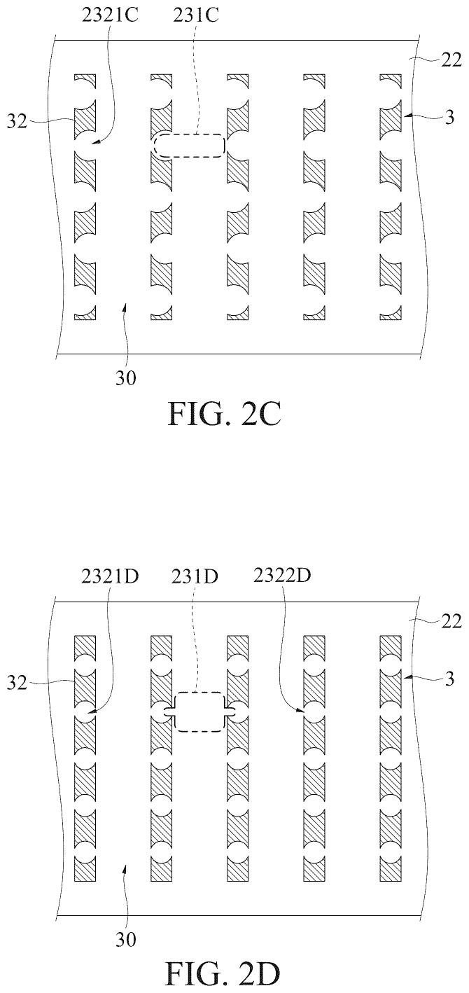

With reference to FIG. 2A to FIG. 2D, which are front views of an embodiment of a boiling enhancement component 1 according to the present disclosure. Specifically, the embodiments shown in FIG. 2A to FIG. 2D primarily differ in the size and configuration of the recessed portions 2321A, 2321B, 2321C, 2321D, and the bubble disturbance regions 231A, 231B, 231C, 231D. In the embodiment of FIG. 2A, the recessed portions 2321A on both sidewalls of the bubble guide channel 30 are arranged in a staggered manner. In the embodiment of FIG. 2B, the recessed portions 2321B on both sidewalls of the bubble guide channel 30 are aligned in a side-by-side correspondence, but the recessed portions 321 on the two opposing sides of the protrusions 32 are not interconnected.

In the embodiment shown in FIG. 2C, the recessed portions 2321C are only arranged on one side wall of the bubble guide channel 30. The recessed portions 2321C each have a relatively larger diameter and extend through along the thickness direction of the protrusions 32. In the embodiment shown in FIG. 2D, the recessed portions 2321D are positioned at the center of the protrusion 32, and each recessed portions has two openings 2322D, each of which facing toward one of the bubble guide channels 30 on either sides. These embodiments demonstrate that the design of the recessed portions 2321A, 2321B, 2321C, and 2321D can be flexibly adjusted in terms of shape, size, and placement to meet specific application requirements.

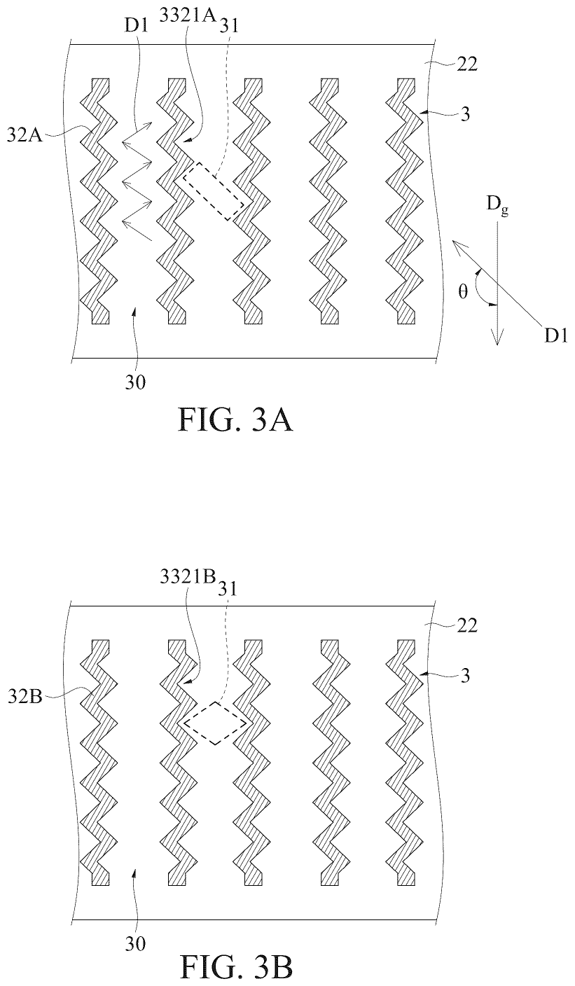

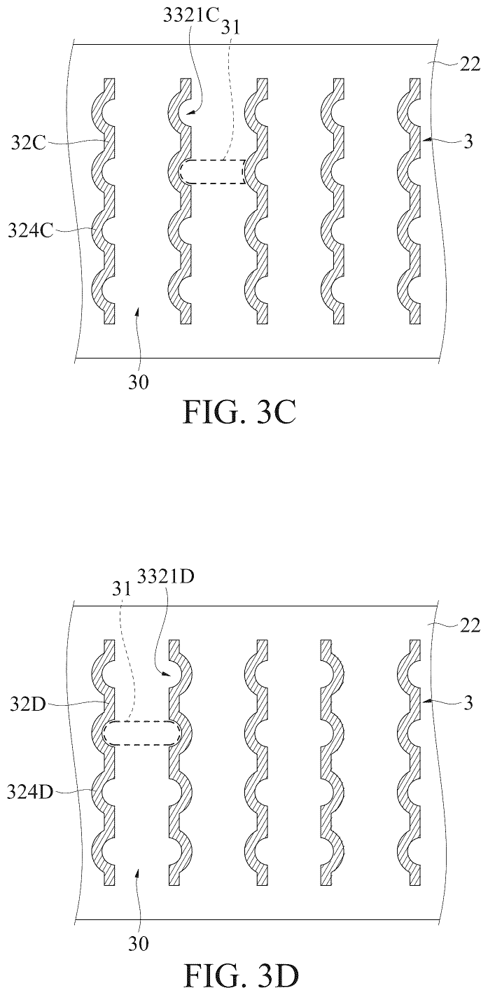

With reference to FIG. 3A to FIG. 3D, which respectively show front views of various embodiments of a boiling enhancement component 1 according to the present disclosure. In further detail, the embodiments presented in FIG. 3A to FIG. 3D primarily differ in the form of the protrusions 32A, 32B, 32C, 32D, and the configuration and shape of the recessed portions 3321A, 3321B, 3321C, 3321D. In the embodiment shown in FIG. 3A, the protrusions 32A are elongated blocks extending along the gravitational direction Dg and each having a zigzag profile, and the recessed portions 3321A are V-shaped grooves. The recessed portions 3321A on the two sidewalls of the bubble guide channel 30 are arranged in a staggered manner, resulting in the bubble guide channel 30 forming a zigzag-shaped path. In this embodiment, the specific direction D1 guiding the upward movement of the bubbles forms an obtuse angle θ relative to the gravitational direction Dg.

In the embodiment shown in FIG. 3B, the protrusions 32B are also zigzag-shaped protrusions, and the recessed portions 3321B are also V-shaped grooves. However, the recessed portions 3321B on the two sidewalls of the bubble guide channel 30 are arranged correspondingly to each other. In the embodiment shown in FIG. 3C, one side of the protrusion 32C is provided with the recessed portions 3321C which are semi-elliptic grooves, while the other side of the protrusion 32C is correspondingly provided with raised portions 324C. As a result, the bubble guide channel 30 forms a meandering pathway. In the embodiment shown in FIG. 3D, one side of the protrusion 32D is provided with the recessed portions 3321D which are also semi-elliptic grooves, while the other side of the protrusion 32C is correspondingly provided with bulged sections 324D. In addition, the recessed portions 3321D arranged on the two side walls of the bubble guide channel 30 are arranged correspondingly.

From the above embodiment, the shape, size, orientation and positions of the protrusions 32 and the recessed portions 321 can be flexibly designed according to actual needs. Additionally, the boiling enhancement component 1 can be made from high thermal conductivity metallic materials, such as copper or aluminum. Regarding the manufacturing methods for the boiling formation portion 3, various processing techniques can be employed, including mechanical machining, photolithography, electroforming, micro-embossing, powder metallurgy, or additive manufacturing (3D printing).

With reference to FIG. 4A and FIG. 4B, FIG. 4A is a bottom view of an embodiment of a boiling enhancement component 41 disposed in a circuit board B according to the present disclosure, and FIG. 4B is a front view of an embodiment of a boiling enhancement component 41 according to the present disclosure. As shown in FIG. 4A, a chip socket S is installed on the circuit board B, and a chip, which serves as the heat source Hs, is mounted on the chip socket S. Above the heat source Hs, a boiling enhancement component 41 is positioned. The boiling enhancement component 41 includes a boiling formation portion 43, which comprises a bubble generation region Zb (see FIG. 4B). This region corresponds to the area on the first surface 21 of the heat conductive portion 2 that is in contact with the heat source Hs. In other words, the bubble generation region Zb is located along the vertical projection of the heat source Hs. Consequently, most of the heat generated by the heat source Hs is directly conducted to the bubble generation region Zb of the boiling formation portion 43 through the shortest thermal path (minimum thermal resistance path) provided by the heat conductive portion 2. The fluid medium (not shown in the figures) will boil in the bubble generation region Zb, producing a large number of bubbles. Specifically, in the embodiment shown in FIG. 4A, the gravity direction Dg is the direction coming out of the plane of the paper.

As shown in FIG. 4B, a plurality of bubble disturbance regions 431 are disposed in the bubble generation region Zb. Each bubble disturbance region 431 is a cylindrical space with a diameter of is 3 mm, and the spacing between adjacent bubble disturbance regions 431 is 8 mm. Additionally, the dimensions of the boiling enhancement component 41 are as follows: length 172.75 mm, width 59.4 mm, and height 4.3 mm, while the thickness of the heat conductive portion 2 is 1.5 mm. The dimensions of each protrusion 432 are as follows: length 49.4 mm, width 0.2 mm, and height 2.8 mm, with a spacing of 0.2 mm between adjacent protrusions 432.

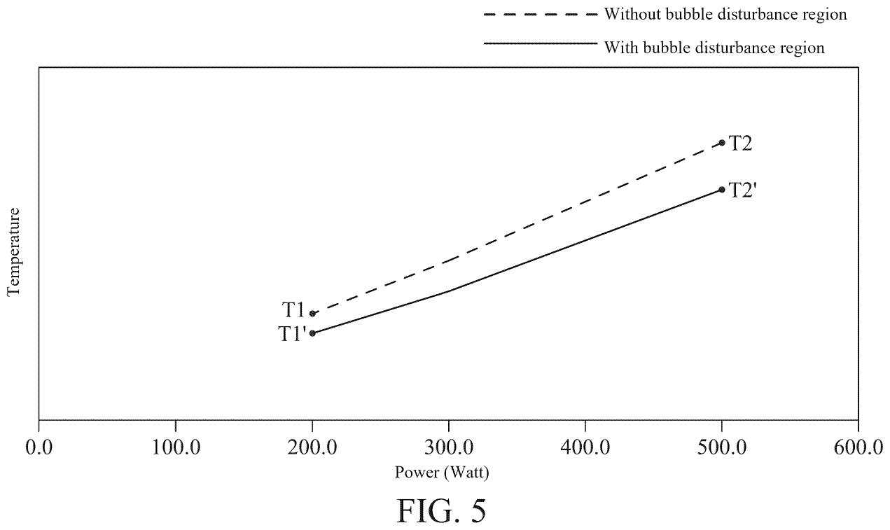

With reference to FIG. 5, FIG. 5 is diagram showing the relationship between temperature and power after the actual operation of an embodiment of the boiling enhancement component 41 according to the present disclosure. The experimental results based on the embodiment and parameters shown in FIGS. 4A and 4B are presented in FIG. 5. When the thermal design power (TDP) of the heat source Hs is 200 W, the chip temperature using a conventional boiler (without the bubble disturbance region 431) is T1, while the chip temperature using the boiling enhancement component 41 with the bubble disturbance region 431 is T1′. When the thermal design power is 500 W, the chip temperature using a conventional boiler is T2, whereas the chip temperature using the boiling enhancement component 41 with the bubble disturbance region 431 is T2′.

As shown in FIG. 5, in terms of chip temperature, the boiling enhancement component 41 with the bubble disturbance region 431 reduces the chip temperature by at least approximately 2.4% to 4.7% compared to a conventional boiler. Regarding thermal resistance, actual measurements and calculations demonstrate that the boiling enhancement component 41 with the bubble disturbance region 431 reduces thermal resistance by at least approximately 16% to 18% compared to a conventional boiler.

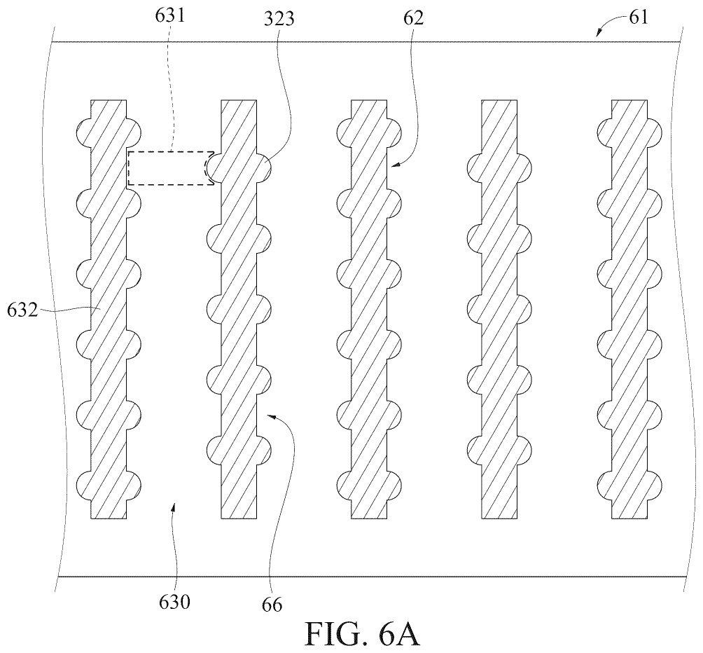

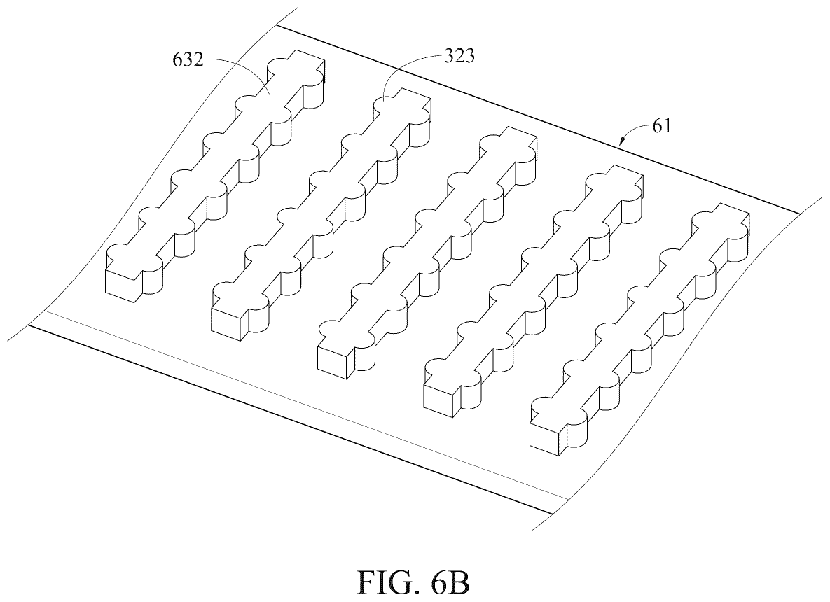

With reference to FIG. 6A and FIG. 6B, FIG. 6A is a front view of an embodiment of a boiling enhancement component 61 according to the present disclosure, and FIG. 6B is a perspective view of an embodiment of a boiling enhancement component 61 according to the present disclosure. The primary difference between this embodiment and the embodiments shown in FIG. 1A and FIG. 1B lies in the replacement of the recessed portions 321 in FIG. 1A and FIG. 1B with raised portions 323 in this embodiment. In other words, the protrusions 632 include raised portions 323 that extend into the bubble guide channel 630. In some embodiments, an interval recess 62 is formed between two adjacent raised portions 323, and the bubble guide channel 630, together with these interval recess 62, constitutes the bubble disturbance region 631.

As described above, the methods of forming the bubble disturbance regions 631 in the present disclosure are not limited. Whether the structure involves the protrusions 632 extending outward or recessing inward, as long as it can alter the geometry of the bubble guide channel 630, thereby adjusting the rising paths of the bubbles and influencing their aggregation behavior, such structural variations fall within the scope of the present disclosure.

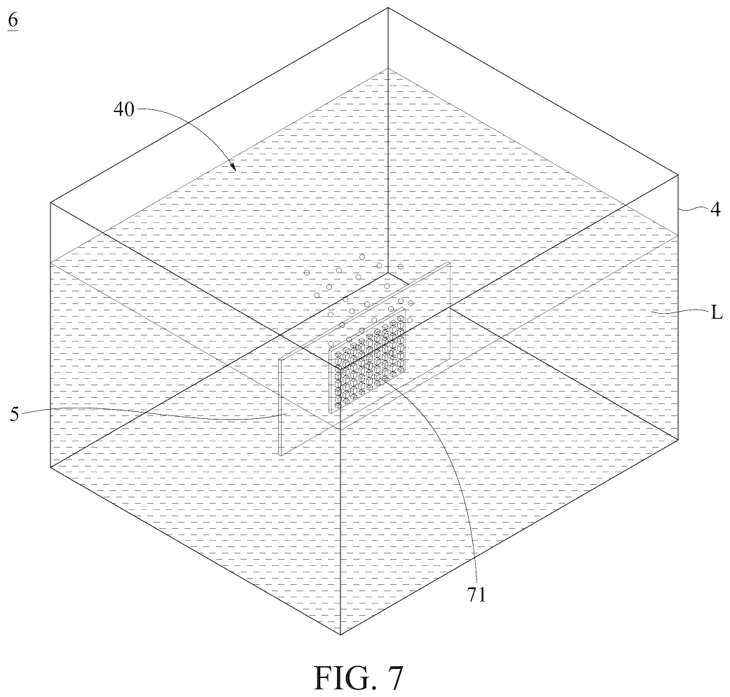

With reference to FIG. 7, which is a schematic diagram of an embodiment of an immersion cooling system 6 according to the present disclosure. As shown in FIG. 7, in some embodiments, the immersion cooling system 6 primarily includes a tank 4, an information processing apparatus 5, and a boiling enhancement component 71. The tank 4 has a containing space 40 suitable for containing a fluid medium L. The fluid medium L may be a non-conductive two-phase cooling liquid with a low boiling point, commonly made of fluorocarbon compound (such as 3M™ Novec™ electronic fluoride liquid). The information processing apparatus 5 may be a server device, and the boiling enhancement component 71 can be any of the boiling enhancement component 71 described in the aforementioned embodiments.

In other embodiments, the system may additionally include a vapor recovery system, such as a condensation pipeline (not shown in the figure), which can be arranged above the tank 4. The vapor recovery system can collect and recover vapor generated by the boiled fluid medium L, and condense the vapor into liquid, which then flows back to the tank 4, thereby achieving a closed-loop cooling cycle. In other embodiments, the effect of cyclic cooling can also be achieved by installing a condenser inside the tank.

Specifically, some embodiments of the present disclosure have at least the following advantages:

Enhancing heat transfer and heat exchange efficiency: In some embodiments, the bubble disturbance regions 31 facilitates rapid detachment of bubbles, reducing the formation of gas barriers between the heated surface and the fluid medium L. This allows the fluid medium L to re-contact the heated surface more quickly, improving heat transfer efficiency. After bubble detachment, “cavity nuclei” or “microcavities” remain on the surface, serving as nucleation sites that promote the formation of new bubbles. This further increases the bubble generation frequency, enhancing boiling heat transfer performance.

Avoiding local overheating and achieving uniform cooling: When bubbles remain attached to the surface of the boiling enhancement component 1 for extended periods, heat cannot be released promptly, potentially causing local overheating. Facilitating bubble detachment helps distribute the heat load, preventing the formation of high-temperature zones and enhancing system stability and lifespan. Additionally, bubble detachment ensures continuous refreshing of the surface of the boiling enhancement component 1 by the fluid medium L, reducing temperature inconsistencies and achieving uniform cooling. This minimizes thermal stress caused by uneven thermal expansion, thereby reducing the risk of damage to electronic components.

Preventing bubble accumulation and channel blockage: If bubbles cannot rise quickly, they may lead to fluid channel blockage. The bubble disturbance regions 31 in some embodiments accelerates the disturbance of the fluid medium L, and promotes bubble ascent. This ensures smooth flow of the fluid medium L, avoiding blockages and improving the system's cooling performance.

Promoting fluid circulation and system stability: As bubbles ascend rapidly, they create local negative pressure behind them, drawing fresh fluid into the area and promoting internal circulation of the fluid medium L. This enhances the overall fluid dynamics of the cooling system. Moreover, bubble detachment quickly releases heat from the system, preventing the “boiling hysteresis effect” caused by local high temperatures. This ensures stable system operation and reduces risks associated with thermal runaway.

Reducing thermal fatigue and extending the lifespan of electronic components: Irregular bubble generation and detachment rates can cause thermal stress fluctuations in the system. Particularly in high-power operational environments, such fluctuations accelerate component fatigue and failure. Facilitating bubble detachment and ascent minimizes temperature fluctuations on the surface of the boiling enhancement component 1, reducing thermal fatigue effects and extending the lifespan of electronic components (heat source Hs).

Supporting higher power density: By promoting bubble detachment and ascent, the system's heat dissipation capability is significantly enhanced, enabling the same cooling structure to handle higher heat power loads. This allows high-power electronic devices such as high-performance computing (HPC) servers, data centers, and GPUs to support higher power densities, mitigating overheating issues and improving device reliability.

In summary, in some embodiments of the present disclosure, the boiling enhancement component 1 accelerates bubble detachment and ascent, significantly improving cooling efficiency and preventing gas accumulation and flow blockage. The boiling enhancement component 1 also promotes fluid medium L flow and circulation, reducing system thermal runaway and thermal fatigue effects. These advantages enable immersion cooling systems 6 to support higher power densities, lower system costs, and enhance system stability and reliability. This is critical for thermal management in high-performance computing (HPC) servers, data centers, and high-power electronic devices.

Although the present disclosure has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A boiling enhancement component, comprising:
a heat conductive portion, comprising a first surface configured to contact a heat source, and a second surface; and
a boiling formation portion, located on the second surface of the heat conductive portion and comprising a plurality of bubble disturbance regions,
wherein in response to that a fluid medium boils on the boiling formation portion to generate a plurality of bubbles, the bubble disturbance regions are configured to redirect a rising path of at least some of the bubbles.

2. The boiling enhancement component according to claim 1, wherein the boiling formation portion comprises at least one bubble guide channel configured to guide the rising of the bubbles; the bubble disturbance regions are located at the at least one bubble guide channel.

3. The boiling enhancement component according to claim 2, wherein the at least one bubble guide channel is substantially parallel to a gravity direction.

4. The boiling enhancement component according to claim 3, wherein the bubble disturbance regions are configured to direct at least some of the bubbles along in a specific direction, the specific direction forming an angle with respect to the gravity direction, and the angle is between 90° and 180°.

5. The boiling enhancement component according to claim 3, wherein the boiling formation portion comprises a plurality of protrusions which arranged along the gravity direction and extending longitudinally; the at least one bubble guide channel is formed among the protrusions.

6. The boiling enhancement component according to claim 5, wherein the protrusions comprise a plurality of recessed portions; the recessed portions each have an opening, the opening facing the at least one bubble guide channel, and the at least one bubble guide channel and the recessed portions form the bubble disturbance regions.

7. The boiling enhancement component according to claim 6, wherein the recessed portions are respectively disposed on two opposite sides of the protrusions and are in communication with each other.

8. The boiling enhancement component according to claim 5, wherein the protrusions comprise a plurality of raised portions which protrudes towards the at least one bubble guide channel; and an interval recess is formed between each two adjacent raised portions, and the at least one bubble guide channel and the interval recess form the bubble disturbance regions.

9. The boiling enhancement component according to claim 1, wherein the boiling formation portion comprises a bubble generation region which corresponds to a region, in contact with the heat source, on the first surface of the heat conductive portion; and the bubble disturbance regions are located in the bubble generation region.

10. A boiling enhancement component, comprising:
a heat conductive portion, comprising a first surface configured to contact a heat source, and a second surface; and
a plurality of protrusions, located on the second surface of the heat conductive portion, arranged along a gravity direction and extending longitudinally, with a plurality of bubble guide channels formed among the protrusions,
wherein surfaces of the protrusions forming the bubble guide channels comprise at least one among a plurality of recessed portions and a plurality of raised portions to redirect a rising path of a plurality of bubbles.

11. The boiling enhancement component according to claim 10, wherein the recessed portions and the raised portions are configured to direct at least some of the bubbles along in a specific direction, the specific direction forming an angle with respect to the gravity direction, and the angle is between 90° and 180°.

12. The boiling enhancement component according to claim 10, wherein the recessed portions each have an opening facing the bubble guide channels, and the bubble guide channels and the recessed portions form a plurality of bubble disturbance regions.

13. The boiling enhancement component according to claim 12, wherein the protrusions comprise a bubble generation region which corresponds to a region, in contact with the heat source, on the first surface of the heat conductive portion; and the bubble disturbance regions are located in the bubble generation region.

14. The boiling enhancement component according to claim 10, wherein the recessed portions are respectively disposed on two opposite sides of the protrusions and are in communication with each other.

15. The boiling enhancement component according to claim 10, wherein an interval recess is formed between each two adjacent raised portions; the at least one bubble guide channel and the interval recess form the bubble disturbance regions.

16. An immersion cooling system, comprising:
a tank, having a containing space configured to accommodate a fluid medium;
a boiling enhancement component, disposed in the containing space of the tank and immersed in a fluid medium; the boiling enhancement component comprises:
a heat conductive portion, comprising a first surface configured to contact a heat source, and a second surface; and
a boiling formation portion, located on the second surface of the heat conductive portion and comprising a plurality of bubble disturbance regions,
wherein in response to that the fluid medium boils on the boiling formation portion and generates a plurality of bubbles, the bubble disturbance regions are configured to redirect a rising path of at least some of the bubbles.

17. The immersion cooling system according to claim 16, wherein the boiling formation portion comprises a plurality of bubble guide channels configured to guide rising of the bubbles; the bubble disturbance regions are located at the bubble guide channels; and the bubble guide channels are substantially parallel to a gravity direction.

18. The immersion cooling system according to claim 17, wherein the bubble disturbance regions are configured to direct at least some of the bubbles along in a specific direction, the specific direction forming an angle with respect to the gravity direction, and the angle is between 90° and 180°.

19. The immersion cooling system according to claim 17, wherein the boiling formation portion comprises a plurality of protrusions which arranged along the gravity direction and extending longitudinally; the bubble guide channels are formed among the protrusions; and the surfaces of the protrusions forming the bubble guide channels comprise at least one of a plurality of recessed portions and a plurality of raised portions.

20. The immersion cooling system according to claim 19, wherein the recessed portions each have an opening facing the at least one bubble guide channel, and the bubble guide channels and the recessed portions form the bubble disturbance regions.

21. The immersion cooling system according to claim 16, further comprising an information processing apparatus which is arranged in the containing space of the tank, wherein the heat source is arranged at the information processing apparatus.
